(19) United States
(12) Patent Application Publication
(10) Pub. No.: US 2025/0038743 A1
(43) Pub. Date: Jan. 30, 2025

(54) ISOLATED SELECTOR AND ASSOCIATED ELECTRONIC DEVICE

(71) Applicant: Realtek Semiconductor Corp., HsinChu (TW)

(72) Inventors: Yu-Cheng Lo, HsinChu (TW); Shu-Yu Chang, HsinChu (TW)

(73) Assignee: Realtek Semiconductor Corp., HsinChu (TW)

(21) Appl. No.: 18/780,442

(22) Filed: Jul. 22, 2024

(30) Foreign Application Priority Data
Jul. 26, 2023 (TW) 112127914

(51) Int. Cl. H03K 17/00; H03K 19/003; H03K 19/0175

(52) U.S. Cl. CPC H03K 17/005; H03K 19/00346; H03K 19/017545

(57) ABSTRACT

An isolated selector and an associated electronic device are provided. The isolated selector receives first data and second data from a first functional circuit and a second functional circuit, respectively, and the isolated selector includes an isolated component, wherein the isolated component receives the first data and generates isolated data according to a control signal and the first data. In addition, the isolated selector selects one of the first data and the second data to be output as output data of the isolated selector. When the isolated selector selects the second data to be output as the output data according to the control signal, the isolated component set the isolated data to be a fixed value according to the control signal, in order to prevent operations of the first functional circuit from interfering with the output data of the isolated selector.

### BACKGROUND OF THE INVENTION

### 1. Field of the Invention

The present invention is related to digital circuits, and more particularly, to an isolated selector and an associated electronic device.

### 2. Description of the Prior Art

Multiple power domains of an electronic device can be selectively turned on or turned off (e.g. multiple sub-circuits within the electronic device can be selectively powered on or powered off). When a signal path within the electronic device crosses different power domains, an output of the signal path needs to be properly controlled so that the output does not interfere with other signal paths. For example, when a circuit within the signal path is powered off, the output of the signal path becomes unpredictable due to some non-ideal effects such as leakage. This unpredictability may interfere with other normally-running signal paths.

Related arts propose utilization of control logic to solve the above problems, but the related art architecture suffers from low integrity. Circuit implementations and control flows also increase the complexity of the overall system. Thus, there is a need for a novel architecture that can implement an isolated mechanism of a signal path across different power domains without introducing any side effect or in a way that is less likely to introduce side effects.

### SUMMARY OF THE INVENTION

An objective of the present invention is to provide an isolated selector and an associated electronic device, in order to perform a performance-power-area (PPA) optimization in an overall system which has multiple power domains.

At least one embodiment of the present invention provides an isolated selector. The isolated selector is coupled to a first functional circuit and a second functional circuit, and the first functional circuit and the second functional circuit output first data and second data, respectively. The isolated selector comprises at least one isolated component, where the at least one isolated component is configured to receive the first data and generate isolated data according to a control signal and the first data. In addition, the isolated selector is configured to select one of the first data and the second data to be output as output data of the isolated selector according to the control signal, and when the isolated selector selects the second data to be output as the output data according to the control signal, the at least one isolated component sets the isolated data to be a fixed value according to the control signal, in order to prevent operations of the first functional circuit from interfering with the output data of the isolated selector.

At least one embodiment of the present invention provides an electronic device. The electronic device comprises a first functional circuit, a second functional circuit, a controller and an isolated selector. The isolated selector is coupled to the controller, the first functional circuit and the second functional circuit. The first functional circuit is configured to output first data, and the second functional circuit is configured to output second data, where the controller is configured to generate a control signal. In addition, the isolated selector is configured to select one of the first data and the second data to be output as output data of the isolated selector according to the control signal. The isolated selector comprises at least one isolated component, where the at least one isolated component is coupled to the first functional circuit, and is configured to receive the first data and generate isolated data according to the control signal and the first data. When the isolated selector selects the second data to be output as the output data according to the control signal, the at least one isolated component sets the isolated data to be a fixed value according to the control signal, in order to prevent operations of the first functional circuit from interfering with the output data of the isolated selector.

The present invention integrates the isolated component and a logic circuit configured for performing a signal selecting mechanism into one digital cell circuit (e.g. the isolated selector mentioned above), to enable the isolated selector mentioned above to properly control a signal path without greatly increasing a complexity of an overall design under a condition where the signal path crosses different power domains. In comparison with the related arts, the isolated selector of the present invention has a higher integrity, which enables associated routing and a number of logic gates to be effectively simplified, thereby achieving the PPA optimization of the overall system.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an electronic device according to an embodiment of the present invention.

FIG. 2 is a diagram illustrating an electronic device according to another embodiment of the present invention.

FIG. 3 is a diagram illustrating an isolated selector according to an embodiment of the present invention.

FIG. 4 is a diagram illustrating related details of the isolated selector shown in FIG. 3 according to an embodiment of the present invention.

FIG. 5 is a diagram illustrating an isolated selector according to another embodiment of the present invention.

### DETAILED DESCRIPTION

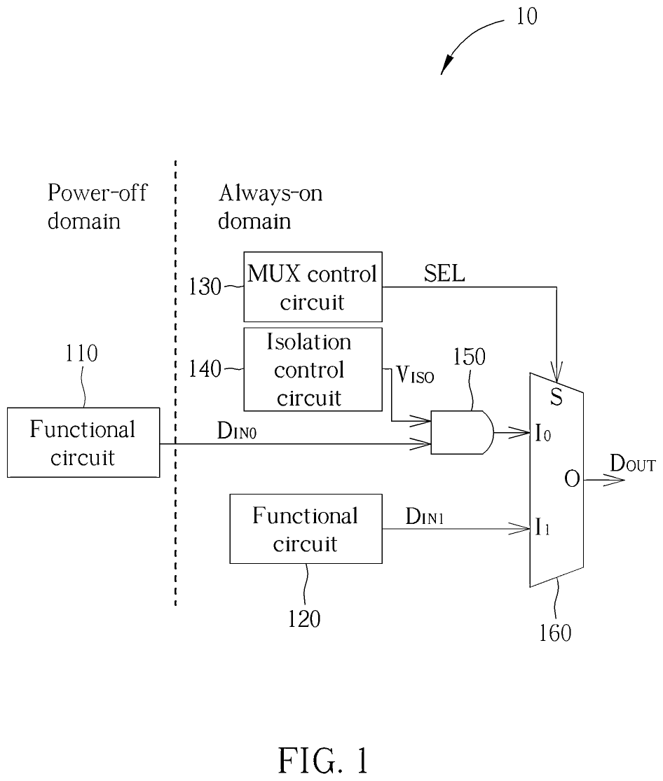

FIG. 1 is a diagram illustrating an electronic device 10 according to an embodiment of the present invention. As shown in FIG. 1, the electronic device 10 may comprise functional circuits 110 and 120, a multiplexer (MUX) control circuit 130, an isolation control circuit 140, at least one isolated component such as an isolated AND gate 150, and a selection circuit such as a MUX 160. In this embodiment, the above components may be divided into multiple power domains according to respective power supplies. For example, under some conditions, a power supply (not shown) of the functional circuit 110 may stop providing power to the functional circuit 110, and a power supply (not shown) of the functional circuit 120, the MUX control circuit 130, the isolation control circuit 140, the isolated AND gate 150 and the MUX 160 may keep providing power to the functional circuit 120, the MUX control circuit 130, the isolation control circuit 140, the isolated AND gate 150 and the MUX 160, where the functional circuit 110 may be regarded as belonging to a power-off domain, and the functional circuit 120, the MUX control circuit 130, the isolation control circuit 140, the isolated AND gate 150 and the MUX 160 may be regarded as belonging to an always-on domain.

In this embodiment, the MUX 160 may select one of data D_{IN0} output from the functional circuit 110 and data D_{IN1} output from the functional circuit 120 according to a control signal SEL generated by the MUX control circuit 130, to be output as output data D_{OUT} of the MUX 160. When the functional circuit 110 is powered on and the data D_{IN0} output from the functional circuit 110 needs to be transmitted to a backend, the isolation controller 140 may set a logic value of a control signal V_{ISO} (e.g. to a logic value “1”) to make the isolation AND gate 150 transmit the data D_{IN0} to a first input terminal (labeled “I₀” in FIG. 1 for brevity) of the MUX 160, and the MUX 160 may select data (e.g. the data D_{IN0} output from the functional circuit 110) received by the first input terminal to be output as the output data D_{OUT} through an output terminal thereof (labeled “O” in FIG. 1 for brevity) according to a logic value of the control signal SEL received by a control terminal thereof (labeled “S” in FIG. 1 for brevity). When the data D_{IN1} output from the functional circuit 120 needs to be transmitted to the backend, the MUX 160 may select data (e.g. the data D_{IN1} output from the functional circuit 120) received by a second input terminal (labeled “I₁” in FIG. 1 for brevity) to be output as the output data D_{OUT} according to the logic value of the control signal SEL, where the isolation control circuit 140 may set the logic value of the control signal V_{ISO} (e.g. to a logic value “0”) to make the isolation AND gate 150 output a fixed value (e.g. the logic value “0”). Thus, even though the value of the data DIN₀ becomes unpredictable as the functional circuit 110 is powered off, the isolation AND gate 150 may transmit the fixed value to the first input terminal of the MUX 160, in order to prevent the data D_{IN0} (which may be unpredictable due to certain factors such as leakage) from interfering with the output data D_{OUT} output from the MUX 160.

In some embodiments, the MUX 160 is implemented by a digital cell circuit of multiple digital circuit cells stored in a digital circuit cell library such as a standard cell library, and the isolated AND gate 150 is further positioned between the MUX 160 and the isolation control circuit 140. Thus, the electronic device 10 needs an additional wire to connect the isolation control circuit 140 and the isolated AND gate 150 for transmitting the control signal V_{ISO} (which is dedicated for controlling the isolated AND gate 150), and needs an additional wire to connect the isolated AND gate 150 and the MUX 160 for transmitting the output of the isolated AND gate 150.

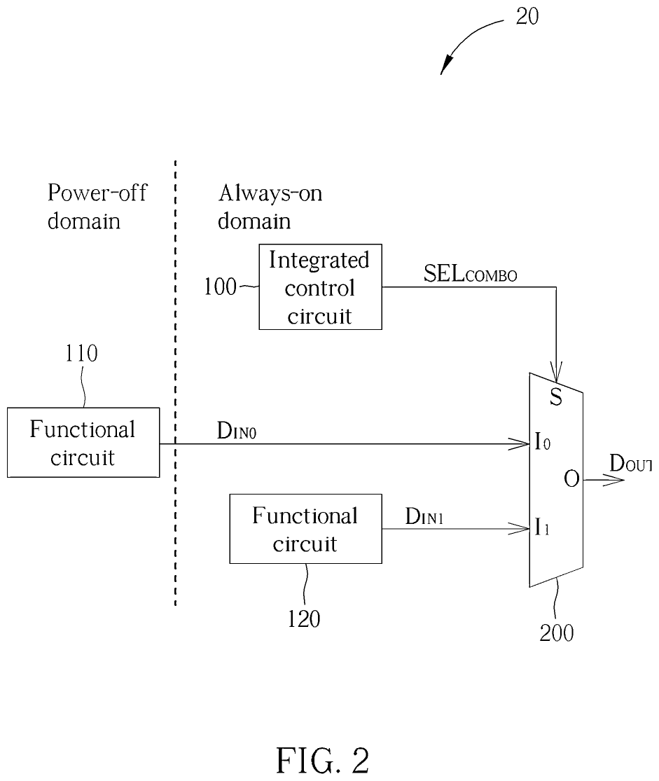

FIG. 2 is a diagram illustrating an electronic device 20 according to another embodiment of the present invention. As shown in FIG. 2, the electronic device 20 may comprise the functional circuits 110 and 120, and may further comprise a controller such as an integrated control circuit 100 (e.g. a combo control circuit) and an isolated selector such as an isolated MUX 200, where a control terminal (labeled “S” in FIG. 2 for brevity) of the isolated MUX 200 is coupled to the integrated control circuit 100, a first input terminal (labeled “I₀” in FIG. 2 for brevity) is coupled to the functional circuit 110, and a second input terminal (labeled “I₁” in FIG. 2 for brevity) is coupled to the functional circuit 120. In this embodiment, the functional circuit 110 may output the data D_{IN0} to the first input terminal of the isolated MUX 200, and the functional circuit 120 may output the data D_{IN1} to the second input terminal of the isolated MUX 200, where the integrated control circuit 100 may be configured to generate a control signal SEL_{COMBO} to the control terminal of the isolated MUX 200.

In this embodiment, the isolated MUX 200 is configured to select one of the data D_{IN0} and the data D_{IN1} to be output as the output data D_{OUT} of the isolated MUX 200 through an output terminal thereof (labeled “O” in FIG. 2 for brevity) according to the control signal SEL_{COMBO}. For example, the isolated MUX 200 may select the data D_{IN0} to be output as the output data D_{OUT} of the isolated MUX 200 in response to a first logic value of the control signal SEL_{COMBO}. In another example, the isolated MUX 200 may select the data D_{IN1} to be output as the output data D_{OUT} of the isolated MUX 200 in response to a second logic value of the control signal SEL_{COMBO}. The isolated MUX 200 may comprise at least one isolated component, where the at least one isolated component is coupled to the functional circuit 110 (e.g. through a first input terminal of the isolated MUX 200), and is configured to receive the data D_{IN0} and generate isolated data according to the control signal SEL_{COMBO} and the data D_{IN0}. More particularly, when the isolated MUX 200 selects the data D_{IN1} to be output as the output data D_{OUT} according to the control signal SEL_{COMBO} (e.g. in response to the second logic value of the control signal SEL_{COMBO}), the at least one isolated component may set the isolated data to be a fixed value according to the control signal SEL_{COMBO} (e.g. in response to the second logic value of the control signal SEL_{COMBO}), in order to prevent operations of the functional circuit 110 from interfering with the output data D_{OUT} of the isolated MUX 200 (e.g. the data D_{IN0} having unpredictable values due to power-off of the functional circuit 110). In addition, when the isolated MUX 200 selects the data D_{IN0} to be output as the output data D_{OUT} according to the control signal SEL_{COMBO} (e.g. in response to the first logic value of the control signal SEL_{COMBO}), the at least one isolated component may output the data D_{IN0} as the isolated data according to the control signal SEL_{COMBO} (e.g. in response to the first logic value of the control signal SEL_{COMBO}), to make the isolated MUX 200 transmit the data D_{IN0} to the output terminal of the isolated MUX 200 through the at least one isolated component.

In comparison with the embodiment of FIG. 1, the embodiment of FIG. 2 integrates the isolated component mentioned above into the isolated MUX 200. More particularly, all components (including the isolated component mentioned above) within the isolated MUX 200 are integrated into a digital cell circuit of multiple digital circuit cells stored in a certain digital circuit cell library such as the standard cell library. Thus, wiring and control related to the isolated component can be effectively simplified. Detailed implementations of integrating the above-mentioned isolated component into the isolated MUX 200 will be described in the following embodiments.

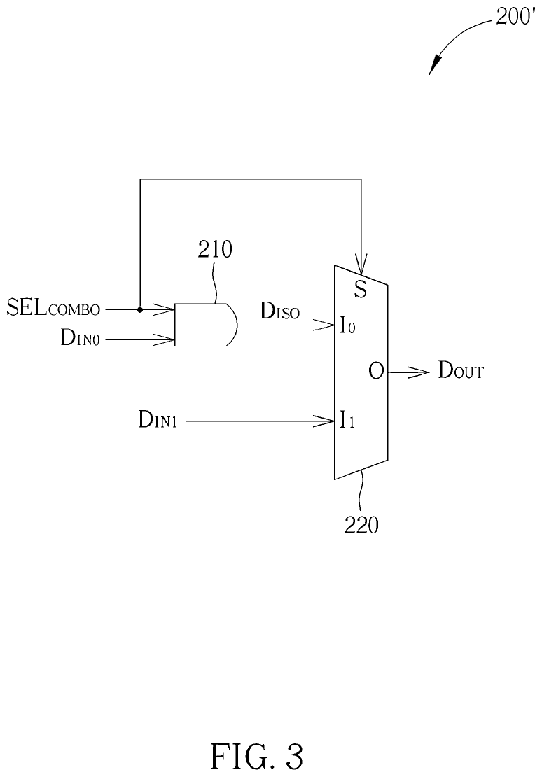

FIG. 3 is a diagram illustrating an isolated MUX 200′ according to an embodiment of the present invention, where the isolated MUX 200′ may be an example of the isolated MUX 200 shown in FIG. 2. As shown in FIG. 3, the isolated MUX 200′ may comprise an isolated AND gate 210 and a selection circuit such as a MUX 220, where the isolated AND gate 210 may be an example of the at least one isolated component mentioned above, and data D_{ISO} output from the isolated AND gate 210 may be an example of the isolated data mentioned above. In this embodiment, a first input terminal (labeled “I₀” in FIG. 3 for brevity) of the MUX 220 may receive the data D_{ISO}, a second input terminal (labeled “I₁” in FIG. 3 for brevity) of the MUX 220 may receive data D_{IN1}, and a control terminal (labeled “S” in FIG. 3 for brevity) of the MUX 220 may receive the control signal SEL_{COMBO}, where an output terminal (labeled “O” in FIG. 3 for brevity) of the MUX 220 may output the output data D_{OUT} of the isolated MUX 200′, and the MUX 220 may be configured to select one of the data D_{ISO} and the data D_{IN1} to be output as the output data D_{OUT} of the isolated MUX 200′ according to the control signal SEL_{COMBO}. More particularly, the isolated AND gate 210 is coupled to the MUX 220, and may be configured to perform an AND logic operation on the control signal SEL_{COMBO} and the data D_{IN0} to generate the isolated data of the at least one isolated component such as the data D_{ISO}.

In this embodiment, when the functional circuit 110 is powered on and the data D_{IN0} output from the functional circuit 110 is transmitted to the backend, the integrated control circuit 100 may set the logic value of the control signal SEL_{COMBO} (e.g. to the logic value “1”) to make the isolated AND gate 210 transmit the data D_{IN0} to the MUX 220 (i.e. D_{ISO}=D_{IN0}), and the MUX 220 may select the data D_{ISO} (i.e. the data D_{IN0}) to be output as the output data D_{OUT} in response to the logic value (e.g. the logic value “1”) of the control signal SEL_{COMBO}. When the data D_{IN1} output from the functional circuit 120 needs to be transmitted to the backend, the integrated control circuit 100 may set the logic value of the control signal SEL_{COMBO} (e.g. to the logic value “0”) to make the MUX 220 select the data D_{IN1} to be output as the output data D_{OUT} in response to the logic value (e.g. the logic value “0”) of the control signal SEL_{COMBO}, where the isolated AND gate 210 may output a fixed value (e.g. the logic value “0”) in response to the logic value (e.g. the logic value “0”) of the control signal SEL_{COMBO}. Thus, even though the value of the data D_{IN0} becomes unpredictable as the functional circuit 110 is powered off, the isolated AND gate 150 may transmit the fixed value to the first input terminal of the MUX 220, in order to prevent the data D_{IN0} (which may be unpredictable due to certain factors such as leakage) from interfering the output data D_{OUT} output from the MUX 220.

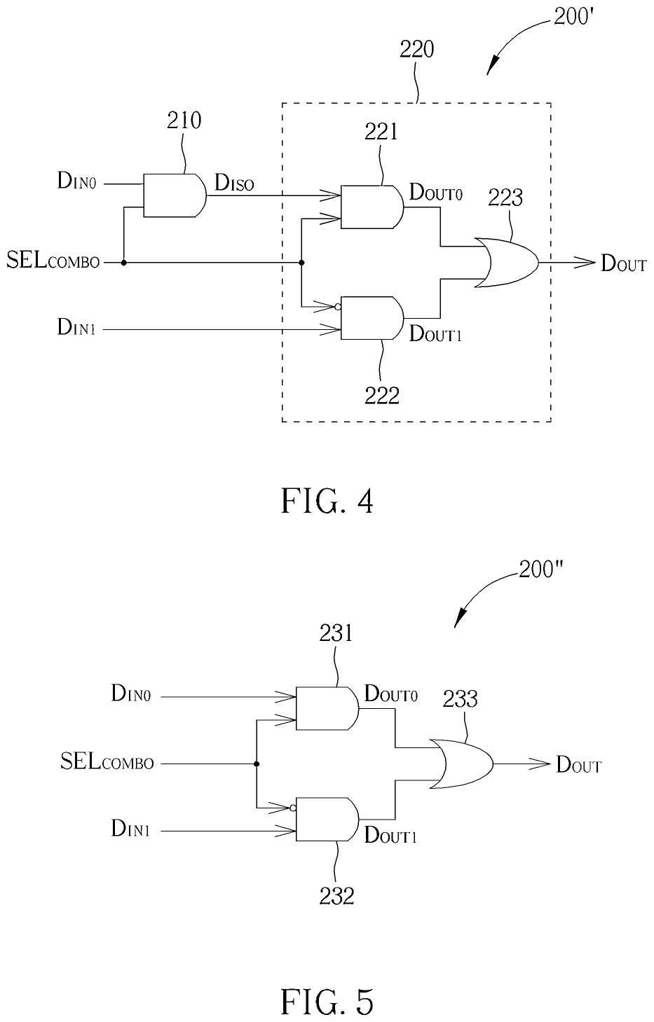

FIG. 4 is a diagram illustrating related details of the isolated MUX 200′ shown in FIG. 3 according to an embodiment of the present invention. In this embodiment, the MUX 220 may comprise a first AND gate such as an AND gate 221, a second AND gate such as an AND gate 222, and an OR gate 223, where the AND gate 221 is coupled to the at least one isolated component such as the isolated AND gate 210 to receive the data D_{ISO}, the AND gate 222 is coupled to the functional circuit 120 (not shown in FIG. 4) to receive the data D_{IN1}, and the OR gate 223 is coupled to the AND gates 221 and 222. In detail, the AND gate 221 is configured to perform a first AND logic operation on the data D_{ISO} and the control signal SEL_{COMBO} to generate a first AND logic result such as data D_{OUT0}, and the AND gate 222 is configured to perform a second AND logic operation on the data D_{IN1} and an inverted signal of the control signal SEL_{COMBO} (illustrated by a circle on an input terminal of the AND gate 222 in FIG. 4 for brevity) to generate a second AND logic result such as data D_{OUT1}, where the OR logic gate 223 is configured to perform an OR logic operation on the data D_{OUT0} and the data D_{OUT1} to generate the output data D_{OUT} of the isolated MUX 200′.

It should be noted that, as the isolated AND gate 210 and the AND gate 221 are the same types of logic gates, the isolated AND gate 210 and the AND gate 221 may be further combined into one AND gate, as shown in FIG. 5.

FIG. 5 is a diagram illustrating an isolated MUX 200″ according to another embodiment of the present invention, where the isolated MUX 200″ may be another example of the isolated MUX 200 shown in FIG. 2. In this embodiment, the isolated MUX 200″ may comprise AND gates 231 and 232, and an OR gate 233, where the OR gate 233 is coupled to the AND gate 231 and 232. More particularly, the AND gate 231 may be an example of the at least one isolated component mentioned above, and may be configured to perform a first AND logic operation on the control signal SEL_{COMBO} and the data D_{IN0} to generate a first AND logic result such as the data D_{OUT0}, where the data D_{OUT0} generated by the AND gate 231 may be regarded as an example of the isolated data mentioned above. In addition, the AND gate 232 is configured to perform a second AND logic operation on the data D_{IN1} and the inverted signal of the control signal SEL_{COMBO} (illustrated by a circle on an input terminal of the AND gate 232 in FIG. 5 for brevity) to generate a second AND logic result such as the data D_{OUT1}, where the OR gate 231 is configured to perform an OR logic operation on the data D_{OUT0} generated by the AND gate 231 and the data D_{OUT1} generated by the AND gate 232 to generate the output data D_{OUT} of the isolated MUX 200″.

It should be noted that, even though the above embodiments utilize AND gates as examples of the at least one isolated component, the present invention is not limited thereto. As long as the at least one isolated component can output a fixed value in response to a specific logic value of the control signal SEL_{COMBO} and this fixed value is not affected by the data D_{IN0} output from the functional circuit 110, implementations of the at least one isolated component may vary (e.g. may be implemented by other types of logic gates). In addition, as long as the logic gate utilized for implementing the at least one isolated component is the same as the logic gate utilized for implementing the first input terminal of the MUX 220, these logic gates may be merged or combined by the manner shown in FIG. 5.

To summarize, the embodiments of the present invention can combine required signals for the isolated component and the MUX into a single control signal (e.g. the control signal SEL_{COMBO}), and combine the isolated component and the MUX into a single digital cell circuit, to make a complexity of associated wiring be effectively reduced. In addition, by merging the same types of logic gates, a total number of logic gates can be effectively reduced, thereby reducing a circuit area and a signal propagation delay. Thus, the isolated selector (e.g. the isolated MUX 200, 200′ and 200″) of the present invention can achieve performance-power-area (PPA) optimization of an overall system.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An isolated selector, comprising:
at least one isolated component, configured to receive first data and generate isolated data according to a control signal and the first data;
wherein the isolated selector is coupled to a first functional circuit and a second functional circuit, the first functional circuit and the second functional circuit output the first data and second data, respectively, the isolated selector is configured to select one of the first data and the second data to be output as output data of the isolated selector according to the control signal, and when the isolated selector selects the second data to be output as the output data according to the control signal, the at least one isolated component sets the isolated data to be a fixed value according to the control signal, in order to prevent operations of the first functional circuit from interfering with the output data of the isolated selector.

2. The isolated selector of claim 1, wherein when the isolated selector selects the first data to be output as the output data according to the control signal, the at least one isolated component outputs the first data as the isolated data according to the control signal, to make the isolated selector transmit the first data to an output terminal of the isolated selector through the at least one isolated component.

3. The isolated selector of claim 1, wherein all components within the isolated selector are integrated in a digital cell circuit of multiple digital circuit cells stored in a digital cell library.

4. The isolated selector of claim 1, further comprising:
a selection circuit, configured to select one of the isolated data and the second data to be output as the output data of the isolated selector according to the control signal.

5. The isolated selector of claim 4, wherein the at least one isolated component comprises:
an AND gate, coupled to the selection circuit, configured to perform an AND logic operation on the control signal and the first data to generate the isolated data of the at least one isolated component.

6. The isolated selector of claim 4, wherein the selection circuit comprises:
a first AND gate, coupled to the at least one isolated component, configured to perform a first AND logic operation on the isolated data and the control signal to generate a first AND logic result;
a second AND gate, coupled to the second functional circuit, configured to perform a second AND logic operation on the second data and an inverted signal of the control signal to generate a second AND logic result; and
an OR gate, coupled to the first AND gate and the second AND gate, configured to perform an OR logic operation on the first AND logic result and the second AND logic result to generate the output data of the isolated selector.

7. The isolated selector of claim 1, wherein the at least one isolated component comprises a first AND gate, the first AND gate is configured to perform a first AND logic operation on the control signal and the first data to generate a first AND logic result to be the isolated data, and the isolated selector further comprises:
a second AND gate, configured to perform a second AND logic operation on the second data and an inverted signal of the control signal to generate a second AND logic result; and
an OR gate, coupled to the first AND gate and the second AND gate, configured to perform an OR logic operation on the first AND logic result and the second AND logic result to generate the output data of the isolated selector.

8. An electronic device, comprising:
a first functional circuit, configured to output first data;
a second functional circuit, configured to output second data;
a controller, configured to generate a control signal; and
an isolated selector, coupled to the controller, the first functional circuit and the second functional circuit, configured to select one of the first data and the second data to be output as output data of the isolated selector according to the control signal, wherein the isolated selector comprises:
at least one isolated component, coupled to the first functional circuit, configured to receive the first data and generate isolated data according to the control signal and the first data;
wherein when the isolated selector selects the second data to be output as the output data according to the control signal, the at least one isolated component sets the isolated data to be a fixed value according to the control signal, in order to prevent operations of the first functional circuit from interfering with the output data of the isolated selector.

9. The electronic device of claim 8, wherein when the isolated selector selects the first data to be output as the output data according to the control signal, the at least one isolated component outputs the first data as the isolated data according to the control signal, to make the isolated selector transmit the first data to an output terminal of the isolated selector through the at least one isolated component.

10. The electronic device of claim 8, wherein all components within the isolated selector are integrated in a digital cell circuit of multiple digital circuit cells stored in a digital cell library.

11. The electronic device of claim 8, wherein the isolated selector further comprises:
a selection circuit, configured to select one of the isolated data and the second data to be output as the output data of the isolated selector according to the control signal.

12. The electronic device of claim 11, wherein the at least one isolated component comprises:
an AND gate, coupled to the selection circuit, configured to perform an AND logic operation on the control signal and the first data to generate the isolated data of the at least one isolated component.

13. The electronic device of claim 11, wherein the selection circuit comprises:
a first AND gate, coupled to the at least one isolated component, configured to perform a first AND logic operation on the isolated data and the control signal to generate a first AND logic result;
a second AND gate, coupled to the second functional circuit, configured to perform a second AND logic operation on the second data and an inverted signal of the control signal to generate a second AND logic result; and
an OR gate, coupled to the first AND gate and the second AND gate, configured to perform an OR logic operation on the first AND logic result and the second AND logic result to generate the output data of the isolated selector.

14. The electronic device of claim 8, wherein the at least one isolated component comprises a first AND gate, the first AND gate is configured to perform a first AND logic operation on the control signal and the first data to generate a first AND logic result to be the isolated data, and the isolated selector further comprises:
a second AND gate, configured to perform a second AND logic operation on the second data and an inverted signal of the control signal to generate a second AND logic result; and
an OR gate, coupled to the first AND gate and the second AND gate, configured to perform an OR logic operation on the first AND logic result and the second AND logic result to generate the output data of the isolated selector.
